(19) United States
(12) Patent Application Publication
(10) Pub. No.: US 2015/0159760 A1
(43) Pub. Date: Jun. 11, 2015

(54) MECHANICAL SEALS

(71) Applicants: Christopher Glyn Booth, Barnsley (GB); Richard Jonathan Smith, Essex (GB)

(72) Inventors: Christopher Glyn Booth, Barnsley (GB); Richard Jonathan Smith, Essex (GB)

(73) Assignee: AES ENGINEERING LTD., Rotherham (GB)

(21) Appl. No.: 14/566,975

(22) Filed: Dec. 11, 2014

(30) Foreign Application Priority Data
Dec. 11, 2013 (GB) 1321937.3

(51) Int. Cl. F16J 15/34; C23C 16/06

(52) U.S. Cl. CPC F16J 15/3496; C23C 16/06

(57) ABSTRACT

A mechanical seal face component having a base material with a high ductility or tensile strength and being substantially covered with a coating for providing a sealing surface. The base material preferably includes carbon or stainless steel. The coating preferably includes hard metal alloy, for example, a tungsten-based alloy, and preferably has a thickness no greater than 1.5 mm, which may be applied by vapor deposition.

### BACKGROUND OF THE INVENTION

1. Field of Invention

The present invention relates, generally, to mechanical seals which are fitted to rotating equipment in virtually all types of industries to separate a first liquid from a second liquid and, more particularly, the present invention relates to seal faces for mechanical seals.

2. Description of the Prior Art

Mechanical seals are common place in a multitude of industries for providing a seal between rotating and stationary components. The seal is created by one sealing face rotating against a stationary sealing face. Commonly, one of these faces is urged toward the other through the use of springs thus providing the required sealing force. Whether this is the rotary or stationary face is dependent on the design of the seal and the application requirement. The seal faces are often required to be a carbide or hard metal alloy to improve wear or to meet chemical compatibility requirements of the face. Where the rotary face is spring energized it is common for it to comprise an carbide or hard metal alloy face inserted into a machined stainless steel holder due to it not being possible, or not being commercially viable, to meet the often complex geometry requirements in accommodating drive pins, springs and sealing grooves into the carbide or hard metal alloy material.

Where the seal is to operate under arduous conditions where the product is corrosive, the stainless steel holder needs to be manufactured from hard metal alloy or a monolithic carbide seal needs to be used; thereby adding cost. Temperature also affects the flatness of the face due to the differences in thermal expansion of the rotary holder material and the inserted face.

There can be limitations to the use of monolithic faces depending on the profiles that can be machined in them. Furthermore, the material characteristics causing failures in high speed duties or where large faces are required.

### SUMMARY OF THE INVENTION

Accordingly, the present invention is directed to a mechanical seal face ring or component that is constructed from a base material that has high ductility and/or tensile strength and is extensively covered with a hard metal or hard metal alloy, preferably a tungsten-based alloy. An advantage of using a tungsten-based alloy is that is it cost effective over other materials, such as tungsten carbide.

Preferably, the hard metal or hard metal alloy is applied via a method of vapor deposition thereby changing the surface properties of the seal face. Vapor deposition, particularly low temperature vapor deposition, allows for the application of a layer of material on the base material.

Advantageously, the seal face or component comprises at least one complex profile, including spring holes, pin holes and O-ring grooves.

Preferably, the base material comprises carbon or stainless steel. These materials are cost-effective and so the wear characteristics of the component can be improved with a layer of the hard metal or hard metal alloy.

It is advantageous that the coating is no more than 1.5 mm in thickness. This provides a sufficiently thick layer to be strong enough to resist wear and provide the necessary hardness, but keeps down the cost of the improved component.

In one preferred embodiment the said sealing surface is ground and lapped flat to within 1-2 light bands.

The present invention overcomes the drawbacks inherent in the prior art by providing a mechanical seal face ring or component that is constructed from a base material that has high ductility and/or tensile strength and is extensively covered by a hard metal alloy, preferably via a method of vapor deposition, thereby changing the surface properties of the seal face.

Accordingly, the seal face is made from an easily machined ductile material, but is metallurgically bonded to a wear-resistant coating of a hard metal alloy that gives it the properties that are required in arduous applications.

Other objects and features of the present invention will become apparent when considered in combination with the accompanying drawing figures, which illustrate certain preferred embodiments of the present invention. It should, however, be noted that the accompanying drawing figures are intended to illustrate only select preferred embodiments of the claimed invention and are not intended as a means for defining the limits and scope of the invention.

### BRIEF DESCRIPTION OF THE DRAWING FIGURES

In the drawing, wherein similar reference numerals and symbols denote similar features throughout the several views:

FIG. 1 is a cross-sectional view of a mechanical seal face with inserted rotary face with inserted rotary face; and,

FIG. 2 is a cross sectional view of a seal face in accordance with the present invention.

### DETAILED DESCRIPTION OF THE DRAWING FIGURES AND PREFERRED EMBODIMENTS

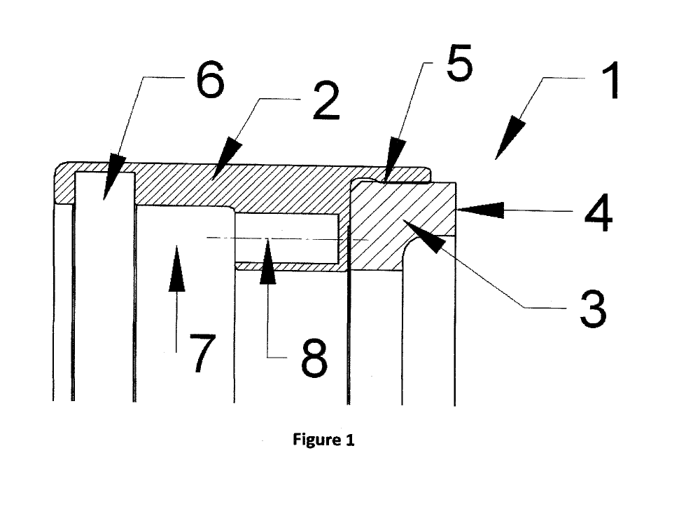

Turning now, in detail, to the drawing figures. FIG. 1 provides a cross-sectional view of a mechanical seal face 1 which comprises a holder 2 and inserted face 3. The inserted face 3 is constructed from a carbide or hard metal alloy which is preferably L-shaped in profile with the outer most axially protruding portion 4 being flat to within 1-2 helium light bands. The rotary holder 2 has an annular cavity 5 in which the inserted face resides and a secondary annular groove 6. A tertiary annular groove 7 has a perpendicular planar surface where a plurality of holes 8 resides for springs and drive pins to be located.

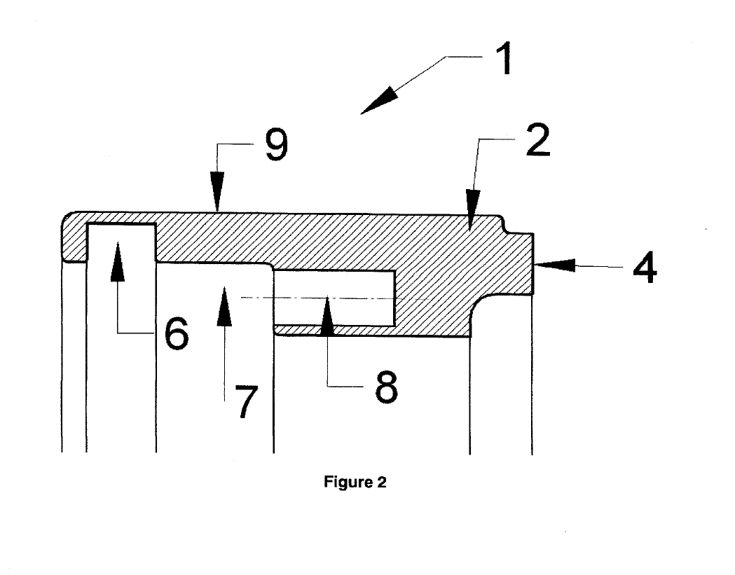

Referring to FIG. 2, a mechanical seal face 1 is shown which is of monolithic construction. The same features as those of the seal of FIG. 1 are included with annular grooves 6 and 7, and a plurality of holes 8 for springs and drive pins to be located. The profile is substantially coated with a layer of hard alloy material 9 thereby changing the characteristics of the base material and also being able to be lapped flat on the face 4 providing a sealing surface.

While only several embodiments of the present invention have been shown and described, it will be obvious to those skilled in the art that many modifications may be made to the present invention without departing from the spirit and scope thereof.

What is claimed is:

1. A mechanical seal face component comprising a base material having a high ductility or tensile strength and being substantially covered with a coating for providing a sealing surface.

2. The mechanical seal face component according to claim 1, further comprising a complex profile.

3. The mechanical seal face component according to claim 2, wherein said complex profile includes at least one of spring holes, pin holes and O-ring grooves.

4. The mechanical seal face component according to claim 1, wherein said base material comprises carbon.

5. The mechanical seal face component according to claim 1, wherein said base material comprises stainless steel.

6. The mechanical seal face component according to claim 1, wherein said coating has a thickness no greater than 1.5 mm.

7. The mechanical seal face component according to claim 1, wherein said sealing surface is ground and lapped flat to within 1-2 light bands.

8. The mechanical seal face component according to claim 1, wherein said coating comprises a hard metal alloy.

9. The mechanical seal face component according to claim 8, wherein said hard metal alloy is a tungsten-based alloy.

10. The mechanical seal face component, wherein said component is a mechanical seal face ring.

11. A method for applying a coating to a mechanical seal component having a base material with high ductility or tensile strength and being substantially covered with a coating for providing a sealing surface, said method comprising the step of:
applying a hard metal alloy via vapor deposition for changing surface properties of the sealing surface of the mechanical seal component.

12. The method for applying a coating to a mechanical seal component having a base material with high ductility or tensile strength and being substantially covered with a coating for providing a sealing surface, wherein said vapor deposition is low temperature vapor deposition.
